(19) United States
(12) Patent Application Publication
(10) Pub. No.: US 2012/0296477 A1
(43) Pub. Date: Nov. 22, 2012

(54) AUXILIARY CONTROLLER, A HVAC SYSTEM, A METHOD OF MANUFACTURING A HVAC SYSTEM AND A METHOD OF STARTING THE SAME

(76) Inventors: Glenn Will Kowald, Carrollton, TX (US); Darko Hadzidedic, Plano, TX (US)

(21) Appl. No.: 13/561,601

(22) Filed: Jul. 30, 2012

Related U.S. Application Data
(62) Division of application No. 12/707,509, filed on Feb. 17, 2010, now Pat. No. 8,260,444.

(51) Int. Cl. G05D 23/00; H05K 13/00

(52) U.S. Cl. 700/276; 29/592.1

(57) ABSTRACT

The disclosure provides a method of starting a heating, ventilation and air conditioning (HVAC) system, a method of manufacturing a HVAC system, a HVAC system, and an integrated controller thereof. In one embodiment, the method of starting includes: (1) receiving an initiation signal at a main system controller of the HVAC system, (2) determining if main controller application information associated with the main system controller is stored thereon, (3) querying an auxiliary controller of the HVAC system when determining the main controller application information is not stored on the main system controller, (4) sending the main controller application information to the main system controller from the auxiliary controller when the auxiliary controller includes the main controller application information and (5) initiating the HVAC system based on the initiation signal and employing the main controller application information sent to the main system controller from the auxiliary controller.

### CROSS-REFERENCE TO RELATED APPLICATIONS

This Application is a Divisional of U.S. application Ser. No. 12/707,509 filed on Feb. 17, 2010, to Glen Will Kowald, entitled “AUXILIARY CONTROLLER OF A HVAC SYSTEM,” currently allowed for issuance, commonly assigned with the present disclosure and incorporated herein by reference.

### TECHNICAL FIELD

This application is directed, in general, to heating, ventilating and air conditioning (HVAC) systems and, more specifically, to maintaining model specific information or identification data for a main system controller of an HVAC system.

### BACKGROUND

HVAC systems can be used to regulate the environment within an enclosure. Typically, an air blower is used to pull air from the enclosure into the HVAC system through ducts and push the air back into the enclosure through additional ducts after conditioning the air (e.g., heating or cooling the air). In HVAC systems, whether a furnace or a coil blower unit, a single integrated electronic controller may be used to direct the operation.

The integrated electronic controllers of the HVAC systems may be used in different HVAC systems of varying sizes and may be used with various brands of products. As such, an electronic controller may require different feature sets depending on the HVAC system in which the integrated electronic controllers are used. As such, different feature sets can be loaded on an electronic controller for a HVAC system that are tailored for the specific HVAC system and/or installation of the specific HVAC system. To provide the proper feature sets for an electronic controller for a specific HVAC system or application, a manufacturer of the HVAC system may load model identification data and/or model specific information on the electronic controller.

### SUMMARY

The disclosure provides, in one aspect, a method of starting a HVAC system. In one embodiment, the method includes: (1) receiving an initiation signal at a main system controller of the HVAC system, (2) determining if main controller application information associated with the main system controller is stored thereon, (3) querying an auxiliary controller of the HVAC system when determining the main controller application information is not stored on the main system controller, (4) sending the main controller application information to the main system controller from the auxiliary controller when the auxiliary controller includes the main controller application information and (5) initiating the HVAC system based on the initiation signal and employing the main controller application information sent to the main system controller from the auxiliary controller.

In another aspect, a method of manufacturing a HVAC system is disclosed. In one embodiment, the method of manufacturing includes: (1) storing main controller application information for a main system controller of the HVAC system in the main system controller during manufacturing of the HVAC system and (2) storing a copy of the main controller application information in an auxiliary controller of the main system controller during the manufacturing.

In yet another aspect, a HVAC system is disclosed. In one embodiment, the HVAC system includes: (1) a main system controller having a main non-volatile memory and configured to direct operation of the HVAC system and store main controller application information associated therewith on the main non-volatile memory (2) an auxiliary controller having (2A) an interface coupled to the main system controller and configured to communicate therewith, (2B) a processor, coupled to the interface and configured to direct the operation of a component of the HVAC system and (2C) an auxiliary non-volatile memory configured to receive a copy of the main controller application information via the interface and store the main controller application information thereon.

In still another aspect, an integrated controller for a HVAC system is disclosed. In one embodiment, the integrated controller includes: (1) an interface coupled to an auxiliary controller of the HVAC system and configured to communicate therewith, the auxiliary controller having an auxiliary non-volatile memory, (2) a processor, coupled to the interface and configured to direct the operation of the HVAC system and (3) a main non-volatile memory coupled to the processor and configured to receive a copy of main controller application information associated with the main system controller via the interface and store the main controller application information, the processor further configured to automatically send a copy of the main controller application information during manufacturing of the HVAC system to the auxiliary controller of the HVAC system to store as back-up data on the auxiliary non-volatile memory of the auxiliary controller.

### BRIEF DESCRIPTION

Reference is now made to the following descriptions taken in conjunction with the accompanying drawings, in which:

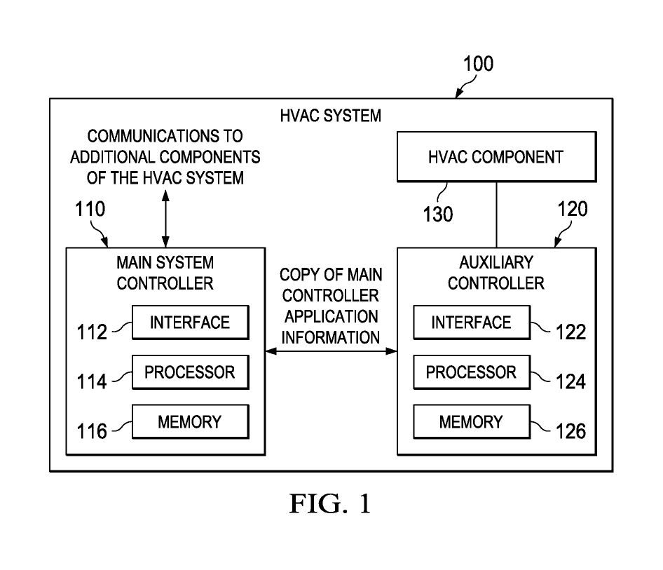

FIG. 1 is a block diagram of an embodiment of a HVAC system constructed according to the principles of the disclosure;

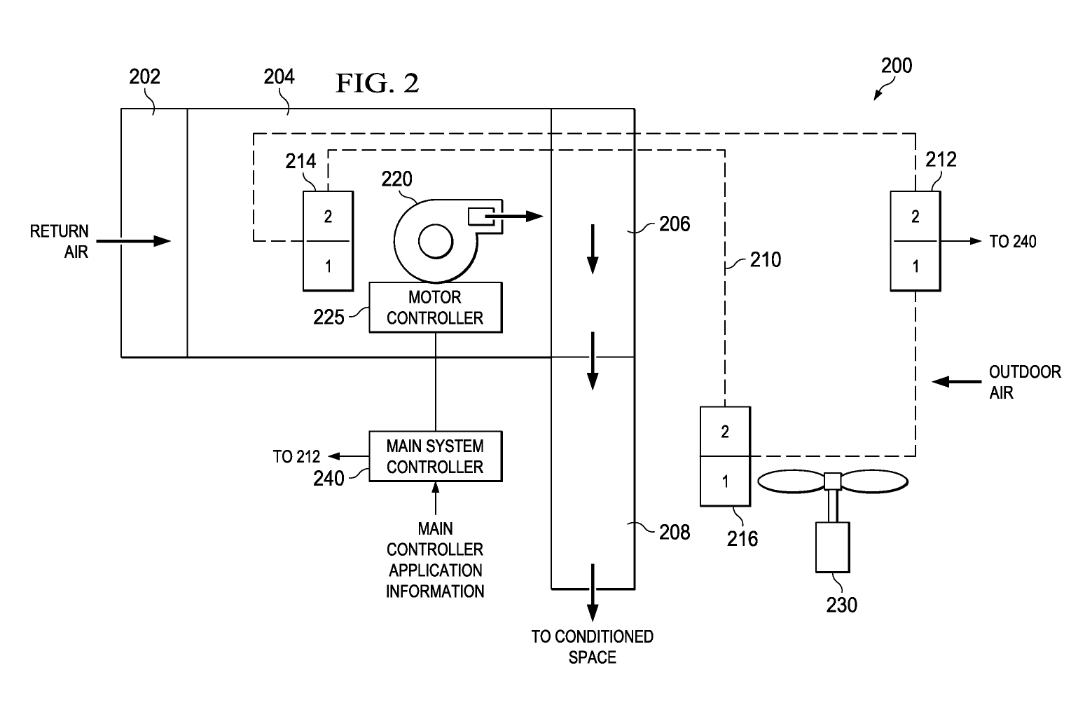

FIG. 2 is a system diagram of an embodiment of a HVAC system constructed according to the principles of the disclosure;

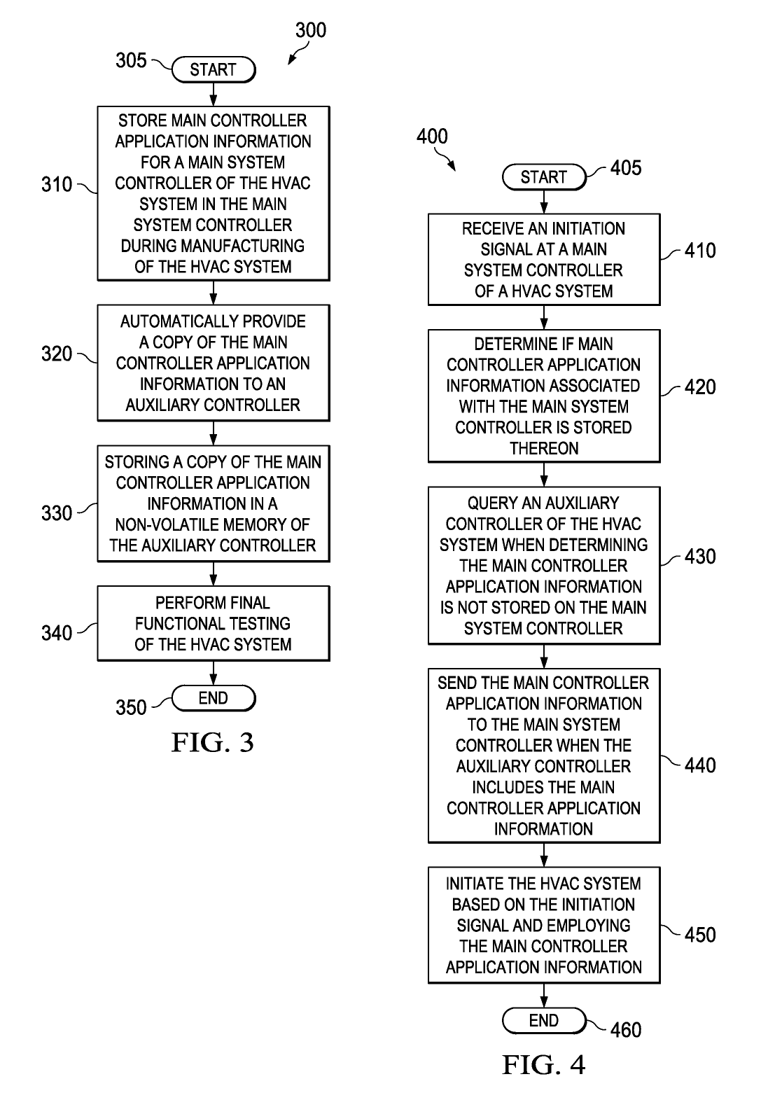

FIG. 3 is a flow diagram of an embodiment of a method of manufacturing a HVAC system carried out according to the principles of the disclosure; and

FIG. 4 is a flow diagram of an embodiment of a method of starting a HVAC system carried out according to the principles of the disclosure.

### DETAILED DESCRIPTION

An Original Equipment Manufacturer (OEM) can load the associated model information or model identification data on the main integrated electronic controller of an HVAC system eliminate the need for additional external hardware that could be required to identify the controller. As such, the cost of construction can be decreased and the ability for standardization can be improved. A negative outcome, however, of storing unit specific information on the main integrated electronic (i.e., main system controller) may be evident during failure and ultimate replacement of the main system controller. In this case, after installing the new controller, the installer or technician can experience an error code upon initial start-up due to missing unit information which will require additional action by the installer to manually select the unit ID. The additional action required by the technician can delay starting an out-of-service HVAC system. Additionally, by relying on the technician to enter the proper model information for the controller, the technician may incorrectly enter the model information. As such, the proper feature set or sets for the main system controller may not be loaded. This may result in improper operation and additional failures of the HVAC system.

Accordingly, the present disclosure provides a copy of main controller application information associated with the main system controller of a HVAC system in at least one auxiliary controller of the HVAC system. The main controller application information is data for the main system controller. The associated data may include model specific information, model identification data, application information for the HVAC system (i.e., information associated with a specific installation of the HVAC system), and feature sets for the HVAC system (general for the HVAC system or specific for the application). By providing a back-up copy of the main controller application information, upon initial power up of a replacement main system controller or a corrupted main system controller, the new or corrupted main controller will realize the model ID or model specific information is not available and will query a controller of an auxiliary component to determine if the needed information is stored thereon. For example, an auxiliary component may be an indoor blower motor and the auxiliary controller a motor controller for the indoor blower motor. If the information is found in the auxiliary controller, then it is sent to the main system controller memory and the operation of the HVAC system can proceed as normal. No error code needs to be displayed and no manual intervention is required by the technician. The specification, therefore, provides embodiments that provide a back-up for the main controller application information and eliminate the need for additional external hardware. As such, the cost of construction can be decreased, the ability for standardization can be improved and the robustness of the system improved.

Typically, each HVAC system will include a designated controller, a main system controller, which is configured to direct the overall operation thereof. As such, the main system controllers disclosed herein are configured to provide control functionality beyond the scope of the present disclosure. The main system controllers may be one or more electric circuit boards including at least one micro-processor or micro-controller integrated circuit. The main system controllers also include the support circuitry for power, signal conditioning, and associated peripheral devices. In addition to a processor, the main system controllers may include a memory having a program or series of operating instruction (i.e., firmware or software) that executes in such a way as to implement at least some of the features described herein when initiated by the processor. The memory includes a non-volatile memory. The auxiliary controllers may be similarly configured and also include a non-volatile memory.

The main controller application information may be copied from the main system controller to the auxiliary controller during manufacturing of the HVAC system. The main controller application information may be automatically copied when the main system controller is loaded with the controller application information. The auxiliary controller may be predetermined. In some embodiments, the auxiliary controller may be a designated auxiliary controller for each type of HVAC system. In some embodiments, the auxiliary controller may vary and could be selected by, for example, a manufacturer.

FIG. 1 is a block diagram of an embodiment of a HVAC system 100 constructed according to the principles of the disclosure. The HVAC system 100 may be, for example, a furnace or a coil blower unit. The HVAC system 100 includes a main system controller 110, an auxiliary controller 120 and a HVAC component 130. In addition to the illustrated component 130, the HVAC system 100 includes additional components as may be typically included in a conventional HVAC system. For example, one skilled in the art will understand that the HVAC system 100 may include heating, cooling and blower (HCB) components that are typically included in a HVAC unit. The additional HCB components are not presently illustrated or discussed but are typically included in an HVAC unit, such as, a compressor, an indoor air blower, an outdoor fan and an electrical heating element. Typical components may also include a power supply, a temperature sensor, etc. The various components of the HVAC system 100 may be contained within a single enclosure (e.g., a cabinet).

The main system controller 110 is configured to direct the operation of the various HCB components. The main system controller 110 includes a communications interface 112, a processor 114 and a memory 116. The communications interface 112 is configured to communicate with the various components of the HVAC system 100. The processor 114 is configured to direct operation of the various components via the communications interface 112. The memory 110 is configured to store a series of operating instructions that direct the operation of the processor 114 when initiated thereby. The memory 116 is non-volatile memory or at least includes a portion that is non-volatile. The memory 116 also includes main controller application information for the main system controller 110. The main controller application information may be loaded in the memory 116 during manufacturing. In some embodiments, the main controller application information may be loaded during the final functional OEM testing of the HVAC system 100. In other embodiments, the main controller application information may be loaded during final functional testing of the main system controller 116 (e.g., a furnace controller). In one embodiment, the main system controller 116 may include information for applicable HVAC system models that was loaded during final functional testing of the main system controller. During final functional testing of the HVAC system 100, the applicable main controller application information that is used (or even an index of a table of the information that was used) may be stored in the memory 116.

A factory programmer (e.g., a computer) may be used to load the main controller application information on the memory 116 at the manufacturer via the interface 112. In some embodiments, the factory programmer may automatically load main controller application information after or as part of the functional testing. In addition to a factory programmer, other computing devices such as a portable computer (e.g., a laptop) or a portable memory device may be used to manually load the main controller application information to the memory 116. The portable memory device may be a “pen drive.” As is widely known, a pen drive, also called a “memory stick” or a “jump drive,” is a solid-state device containing non-volatile computer memory, typically flash random-access memory (RAM), and a Universal Serial Bus (USB) port that allows external access to the non-volatile memory.

The auxiliary controller 120 also includes an interface 122, a processor 124 and a memory 126. The memory 126 is a non-volatile memory or at least includes a portion that is non-volatile. The interface 122 is coupled to the main system controller 110 via the interface 112 and is configured to communicate therewith. The interface 122 is also coupled to the HVAC component 130 and configured to communicate therewith.

The interfaces 112, 122, may be conventional communication ports and may be coupled via a system bus. The system bus may be a typical bus that is employed in HVAC systems. The processor 124 is coupled to the interface 122 and is configured to direct the operation of the HVAC component 130. The memory 126 is configured to store a series of operating instructions that direct the operation of the processor 124 when initiated thereby. The memory 126 may also include various parameters associated with the HVAC component 130 that are employed to operate the HVAC component 130. In addition, the memory 126 is also configured to receive the main controller application information from the main system controller 110 via the interfaces 112, 122, and store the main controller application information in the non-volatile memory of the auxiliary controller 120. The main controller application information may be automatically copied to the non-volatile memory of the memory 126 at the manufacturer of the HVAC system 100. In some embodiments, the controller application information may be manually loaded on the auxiliary controller 120 via the interface 122 employing a computing or memory device.

The HVAC component 130 may be an indoor blower motor for the HVAC system 100. In such an embodiment, the auxiliary controller 120 is an indoor blower motor controller. FIG. 2 provides an embodiment of an HVAC system wherein the auxiliary component is an indoor blower motor.

FIG. 2 is a system diagram of an embodiment of HVAC system 200 constructed according to the principles of the disclosure. The HVAC system 200 includes a return duct 202, a return plenum 204, a supply duct 206 and a supply plenum 208. Additionally, the HVAC system 200 may include a refrigeration circuit having a compressor system 212, evaporator coils 214 and condenser coils 216, an indoor air blower 220, a motor controller 225, an outdoor fan 230 and a main system controller 240. Each of the components of the refrigeration circuit 210 is fluidly coupled together. In this embodiment, the compressor system 212, the evaporator coils 214, and the condenser coils 216 each include two units as denoted by the numbers 1-2 in FIG. 2. The multiple units of the refrigeration system 210 represent two cooling stages of the HVAC system 200. One skilled in the art will understand that this disclosure also applies to other HVAC embodiments having a single cooling stage, more than two cooling stages or no cooling stages. For example, one skilled in the art will also understand that this disclosure and the main system controller applies to other HVAC systems such as a furnace.

One skilled in the art will also understand that the HVAC system 200 may include additional components and devices that are not presently illustrated or discussed but are typically included in an HVAC system, such as, a power supply, a temperature sensor, a humidity sensor, etc. A thermostat (not shown) is also typically employed with the HVAC system 200 and used as a user interface. The various illustrated components of the HVAC system 200 may be contained within a single enclosure (e.g., a cabinet). In one embodiment, the HVAC system 200 may be a rooftop unit.

The refrigeration circuit 210, the indoor air blower 220, the outdoor fan system 230 and the humidity sensor 240 may be conventional devices that are typically employed in HVAC systems. At least some of the operation of the HVAC system 200 can be controlled by the main system controller 240 based on inputs from various sensors of the HVAC system 200 including a temperature sensor or a humidity sensor. For example, the main system controller 240 can employ the motor controller 225 to cause the indoor air blower 220 to move air across the evaporator coils 214 and into an enclosed space.

The motor controller 225 includes an interface, a processor and a non-volatile memory that is used to store a copy of the main controller application information for the main system controller 240. The copy of the main controller application information may be used as a back-up if, for example, the controller application information on the main system controller 240 becomes corrupted. Additionally, the main controller application information stored on the motor controller 225 may be use when a new main system controller is installed. The new main system controller can query the motor controller 225 to determine if the main controller application information is stored thereon and obtain the main controller application information therefrom.

The main system controller 240 may include a processor, such as a microprocessor, configured to direct the operation of the HVAC system 200. Additionally, the main system controller 240 may include an interface and a memory section, having a non-volatile memory, coupled thereto. The interface and memory section may be configured to communicate (i.e., receive and transmit) and store main controller application information for the main system controller 240. The main controller application information for the main system controller 240 can include model specific information and model identification data. The model specific information may include feature sets that are applicable to the particular HVAC system 200. In addition to being uniquely tailored for the HVAC system 200, the main controller application information may also be uniquely tailored to an application of the HVAC system 200 for the customer.

The interfaces of the motor controller 225 and the main system controller 240 may include multiple ports for transmitting and receiving data. The ports may be conventional receptacles for communicating data via various means such as, a portable memory device, a PC or portable computer or a communications network. The interfaces are coupled to the memory sections of the controllers, which may be designed as a conventional memory that is constructed to store data and computer programs and include a non-volatile memory.

As illustrated in FIG. 2, the main system controller 240 is coupled to the various components of the HVAC system 200. In some embodiments, the connections therebetween are through a wired-connection. A conventional cable and contacts may be used to couple the main system controller 240 to the various components of the HVAC system 200. In other embodiments, a wireless connection may also be employed to provide at least some of the connections.

FIG. 3 is a flow diagram of an embodiment of a method 300 of manufacturing a HVAC system carried out according to the principles of the disclosure. The HVAC system may be a furnace, a coil blower unit, a commercial unit, a residential unit, a rooftop unit, etc. The method begins in a step 305.

Main controller application information for a main system controller of the HVAC system is stored in the main system controller during manufacturing of the HVAC system in a step 310. In some embodiments, the main controller application information may be loaded onto the main system controller during final functional testing. The main controller application information may be automatically loaded on the main system controller. The main controller application information may be automatically loaded after the final functional testing or may be loaded as part of the final functional testing. A factory programmer may automatically load the main controller application information.

In a step 320, a copy of the main controller application information is automatically provided to the auxiliary controller. In one embodiment, the copy may be automatically transferred from the main system controller to the auxiliary controller. The main system controller may be configured to automatically transfer the main controller application information upon receipt thereof. As such, the main system controller may be programmed to automatically transfer a copy of the main controller application information to a designated auxiliary controller having a non-volatile memory after receiving the main controller application information. The copy may be transferred via a system bus that couples the main system controller and the auxiliary controller. The system bus may be wireless or wired. In some embodiments, a copy of the main controller application information may be sent to more than one auxiliary controller employing, for example, the system bus.

A copy of the main controller application information is then stored in a memory of the auxiliary controller in a step 330. The main controller application information is stored in a non-volatile memory of the auxiliary controller. In some embodiments, the main controller application information may be stored simultaneously or substantially simultaneously on the main system controller and the auxiliary controller. As such, in these embodiments the main controller application information can also be sent simultaneously or substantially simultaneously to the main system controller and the auxiliary controller. The factory programmer may be configured to send the main controller application information to both of the controllers at the same or substantially the same time.

In a step 340, final functional testing of the HVAC system is performed. The functional testing may be performed by the manufacturer to ensure each component is working correctly and each of the components is working together. The functional testing may also be applied to assess the response to and the recovery from a power failure. Final functional testing is typically performed on a HVAC system before shipment from the manufacturer. The final functional testing for a particular component, such as a main system controller, may be performed by the OEM of that component. Final functioning of the HVAC system may be performed by the manufacturer of the HVAC system or HVAC unit. The method 300 then ends in a step 350.

FIG. 4 is a flow diagram of an embodiment of a method 400 of starting a HVAC system carried out according to the principles of the disclosure. The HVAC system may be turned-on simply after being turned-off. Alternatively, the HVAC system may be started after being out-of-service due to repairs or maintenance. In some embodiments, the HVAC system may be turned-on after replacing the main system controller. The method 400 may be reflected as a series of operating instructions representing an algorithm for starting the HVAC system. The operating instructions or some of the operating instructions may be stored on a main system controller and an auxiliary controller. Thus, a processor or processors may be configured to perform the various steps of the method 400. The method 400 starts in a step 405.

In a step 410, an initiation signal is received at a main system controller of the HVAC system. The initiation signal is a power-up signal that can be generated via the operation of a switch. A technician may start the initiation signal by depressing a switch.

After powering-up, a determination is made in a step 420 if the main controller application information associated with the main system controller is stored thereon. The determination may be automatically started based on receipt of the initiation signal. If the main controller application information is not stored on the main system controller, an auxiliary controller is queried in a step 430 to determine if the auxiliary controller includes the main controller application information. If the auxiliary controller includes the main controller application information, the auxiliary controller sends the main controller application information to the main system controller in a step 440. Both the querying and the sending are performed automatically. The main system controller and the auxiliary controller can be programmed accordingly to automatically perform these steps. The HVAC system is then initiated in a step 450 employing the controller application information. The method 400 ends in a step 460.

Those skilled in the art to which this application relates will appreciate that other and further additions, deletions, substitutions and modifications may be made to the described embodiments. One skilled in the art will understand that the order of the steps of the various methods disclosed herein may vary unless specifically noted otherwise.

What is claimed is:

1. A method of starting a heating, ventilating and air conditioning (HVAC) system, comprising:
receiving an initiation signal at a main system controller of said HVAC system;
determining if main controller application information associated with said main system controller is stored thereon;
querying an auxiliary controller of said HVAC system when determining said main controller application information is not stored on said main system controller;
sending said main controller application information to said main system controller from said auxiliary controller when said auxiliary controller includes said main controller application information; and
initiating said HVAC system based on said initiation signal and employing said main controller application information sent to said main system controller from said auxiliary controller.

2. The method as recited in claim 1 wherein said auxiliary controller is a predetermined auxiliary controller of said HVAC system.

3. The method as recited in claim 1 wherein said determining, querying and sending are performed automatically.

4. The method as recited in claim 1 wherein said controller application information includes feature sets for said main system controller.

5. The method as recited in claim 1 wherein said receiving occurs after installing said main system controller as a replacement controller for said HVAC system.

6. A method of manufacturing a heating, ventilating and air conditioning (HVAC) system, comprising:
storing main controller application information for a main system controller of said HVAC system in said main system controller during manufacturing of said HVAC system; and
storing a copy of said main controller application information in an auxiliary controller of said main system controller during said manufacturing.

7. The method as recited in claim 6 wherein said auxiliary controller is designed to direct the operation of a single component of said HVAC system.

8. The method as recited in claim 6 wherein said storing said main controller application information in said main system controller and said auxiliary controller are performed substantially simultaneously.

9. The method as recited in claim 6 further comprising automatically sending a copy of said main controller application information from said main system controller to said auxiliary controller after storing said main controller application information in said main system controller.

10. The method as recited in claim 6 wherein said storing said main controller application information in said main system controller and said auxiliary controller are performed during final functional testing of said HVAC system.

11. A heating, ventilating and air conditioning (HVAC) system, comprising:
a main system controller having a main non-volatile memory and configured to direct operation of said HVAC system and store main controller application information associated therewith on said main non-volatile memory;
an auxiliary controller, including:
an interface coupled to said main system controller and configured to communicate therewith;
a processor, coupled to said interface and configured to direct the operation of a component of said HVAC system; and
an auxiliary non-volatile memory configured to receive a copy of said main controller application information via said interface and store said main controller application information thereon.

12. The HVAC system as recited in claim 11 further comprising an indoor blower motor configured to move air through said HVAC system, wherein said auxiliary controller is a blower motor controller for said blower motor.

13. The HVAC system as recited in claim 11 wherein said HVAC system includes a furnace and said main system controller is an integrated furnace controller.

14. The HVAC system as recited in claim 11 wherein said HVAC system includes a coil blower unit and said main system controller is an integrated blower controller.

15. The HVAC system as recited in claim 11 wherein said main system controller is configured to store said main controller application information thereon and automatically provide said copy of said controller application information to said auxiliary controller as back-up data.

16. An integrated controller for an HVAC system, comprising:
an interface coupled to an auxiliary controller of said HVAC system and configured to communicate therewith, said auxiliary controller having an auxiliary non-volatile memory;
a processor, coupled to said interface and configured to direct the operation of said HVAC system; and
a main non-volatile memory coupled to said processor and configured to receive a copy of main controller application information associated with said main system controller via said interface and store said main controller application information, said processor further configured to automatically send a copy of said main controller application information during manufacturing of said HVAC system to said auxiliary controller of said HVAC system to store as back-up data on said auxiliary non-volatile memory of said auxiliary controller.
